(19) United States
(12) Patent Application Publication
(10) Pub. No.: US 2025/0022834 A1
(43) Pub. Date: Jan. 16, 2025

(54) SEMICONDUCTOR PACKAGE AND METHOD FOR MANUFACTURING THE SAME

(71) Applicant: Samsung Electronics Co., Ltd., Suwon-si (KR)

(72) Inventor: CHOONGBIN YIM, Suwon-si (KR)

(21) Appl. No.: 18/444,374

(22) Filed: Feb. 16, 2024

(30) Foreign Application Priority Data
Jul. 14, 2023 (KR) 10-2023-0091956

(51) Int. Cl. H01L 23/00; H01L 23/31; H01L 23/498; H01L 23/528; H01L 25/00; H01L 25/065; H01L 25/18

(52) U.S. Cl. CPC H01L 24/48; H01L 23/3128; H01L 23/49822; H01L 23/5286; H01L 24/16; H01L 24/32; H01L 24/73; H01L 25/0652; H01L 25/18; H01L 25/50; H01L 2224/16225; H01L 2224/32145; H01L 2224/48229; H01L 2224/73253; H01L 2224/73265; H01L 2924/181

(57) ABSTRACT

An embodiment of the present invention provides a semiconductor package including: a first redistribution layer structure; a semiconductor stack structure on the first redistribution layer structure, the semiconductor stack structure including a first semiconductor die and a second semiconductor die on the first semiconductor die; a plurality of wires configured to electrically connect the second semiconductor die to the first redistribution layer structure; a substrate on the first redistribution layer structure and around the semiconductor stack structure; a molding material configured to mold the semiconductor stack structure and the wires on the first redistribution layer structure; and forming a second redistribution layer structure on the molding material.

### CROSS-REFERENCE TO RELATED APPLICATION

This application claims priority to and the benefit of Korean Patent Application No. 10-2023-0091956, filed in the Korean Intellectual Property Office on Jul. 14, 2023, the entire contents of which are herein incorporated by reference.

### BACKGROUND

### (a) Field

The present disclosure relates to a semiconductor device and a fabricating method thereof.

### (b) Description of the Related Art

The semiconductor industry seeks to increase integration density so that more passive or active devices can be integrated within a given area. In the development of technology for miniaturizing a circuit line width of a front-end semiconductor process, advancements in miniaturizing circuit line widths within the front-end semiconductor process have encountered challenges. Consequently, the semiconductor industry has been inclined to address these limitations by pioneering semiconductor packaging techniques that enable higher integration densities. According to this trend, package on package (POP) technology has been developed. In PoP technology, a plurality of stacked semiconductor dies are positioned side by side on a front side redistribution layer (FRDL) structure and a memory semiconductor die is positioned on a back side redistribution layer (BRDL) structure, and the FRDL structure and the BRDL structure are connected with each other with conductive posts.

In the PoP technology, among a plurality of semiconductor dies stacked on the front side redistribution layer structure, an upper semiconductor die is electrically connected to the front side redistribution layer structure via the back side redistribution layer structure and the conductive posts. This results in a long electrical path from the upper semiconductor die to the front side redistribution layer structure, and such long electrical paths make it difficult to implement a high-performance semiconductor package.

In addition, in the POP technology, in order to form a metal post, a same process such as exposure, development, etching, and deposition must be repeatedly performed, and accordingly, a turnaround time (TAT) may increase. Thus, a risk of yield degradation may occur in the process of forming the metal post.

Accordingly, it is desirable to develop a new semiconductor package technology that can solve the problems of the conventional semiconductor package technology.

### SUMMARY

In package on package technology, an upper semiconductor die among semiconductor dies stacked on a front side redistribution layer structure and the front side redistribution layer structure may be electrically connected through wire bonding.

In the package on package technology, the front side redistribution layer structure and a back side redistribution layer structure may be electrically connected by using an embedded trace substrate (ETS) instead of a conductive post.

An embodiment of the present invention provides a semiconductor package including: a first redistribution layer structure; a semiconductor stack structure on the first redistribution layer structure, the semiconductor stack structure including a first semiconductor die and a second semiconductor die on the first semiconductor die; a plurality of wires configured to electrically connect the second semiconductor die to the first redistribution layer structure; a substrate on the first redistribution layer structure and around the semiconductor stack structure; a molding layer molding the semiconductor stack structure and the wires on the first redistribution layer structure; and forming a second redistribution layer structure on the molding layer.

An embodiment of the present invention provides a semiconductor package including: a first redistribution layer structure; a plurality of first bonding pads on the first redistribution layer structure; a plurality of second bonding pads on the first redistribution layer structure; a plurality of semiconductor stack structures on the first bonding pads, each of the semiconductor stack structures including a first semiconductor die and a second semiconductor die on the first semiconductor die; a plurality of wires configured to electrically connect the second semiconductor die to the first redistribution layer structure, a first end of each of the wires contacting each of the second bonding pads, and a second end of the wires contacting the second semiconductor die; a substrate positioned side by side with the semiconductor stack structures and around the semiconductor stack structures on the first redistribution layer structure; a molding material configured to mold the semiconductor stack structures and the wires on the first redistribution layer structure; a second redistribution layer structure on the molding material; and a third semiconductor die on the second redistribution layer structure.

An embodiment of the present invention provides a fabricating method of a semiconductor device, including: forming a first redistribution layer structure; bonding a substrate including a through opening onto the first redistribution layer structure, wherein the through opening exposes the first redistribution layer structure; mounting a semiconductor stacked structure on the first redistribution structure and within the through opening, the semiconductor stack structure including a first semiconductor die and a second semiconductor die on the first semiconductor die; connecting the second semiconductor die to the first redistribution layer structure with a plurality of wires; molding the semiconductor stack structure and the wires with a molding material on the first redistribution layer structure; and mounting a second redistribution layer structure on the molding material.

In package on package technology, an upper semiconductor die among semiconductor dies stacked on a front side redistribution layer structure and the front side redistribution layer structure may be electrically connected through wire bonding. As a result, a high-performance semiconductor package may be implemented by reducing the electrical path from the upper semiconductor die to the front side redistribution layer structure.

In the package on package technology, the front side redistribution layer structure and a back side redistribution layer structure may be electrically connected by using an embedded trace substrate (ETS) instead of a conductive post. Accordingly, a length of the electrical path between the front side redistribution layer structure and the back side redistribution layer structure may be reduced, use of metal posts within the semiconductor package may be reduced, a turnaround time may be reduced, and yield may be improved.

### BRIEF DESCRIPTION OF THE DRAWINGS

FIG. 1 illustrates a cross-sectional view showing a semiconductor package according to an embodiment.

FIG. 2 illustrates a cross-sectional view showing a semiconductor package according to an embodiment.

FIG. 3 illustrates a top plan view showing that a second semiconductor die and a front-side redistribution layer structure are connected by wire bonding in a semiconductor package of the embodiment of FIG. 1 and FIG. 2.

FIG. 4 to FIG. 17 each illustrate a cross-sectional view showing a manufacturing method of a semiconductor package according to the embodiment of FIG. 1.

### DETAILED DESCRIPTION

The present disclosure will be described more fully hereinafter with reference to the accompanying drawings, in which embodiments of the present disclosure are shown. As those skilled in the art would realize, the described embodiments may be modified in various different ways, all without departing from the spirit or scope of the present disclosure.

To clearly describe the present disclosure, parts that are irrelevant to the description in the drawings are omitted, and like numerals refer to like or similar constituent elements throughout the specification.

Further, since sizes and thicknesses of constituent members shown in the accompanying drawings are arbitrarily given for better understanding and ease of description, the present disclosure is not limited to the illustrated sizes and thicknesses.

Throughout this specification and the claims that follow, when it is described that an element is “coupled/connected” to another element, the element may be “directly coupled/connected” to the other element or “indirectly coupled/connected” to the other element through a third element. In addition, unless explicitly described to the contrary, the word “comprise” and variations such as “comprises” or “comprising” will be understood to imply the inclusion of stated elements but not the exclusion of any other elements.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

Further, throughout the specification, the phrase “in a plan view” means when an object portion is viewed from the above, and the phrase “in a cross-sectional view” means when a cross-section taken by vertically cutting an object portion is viewed from the side.

Hereinafter, a semiconductor package 100 and a manufacturing method of the semiconductor package 100 according to an embodiment will be described with reference to drawings.

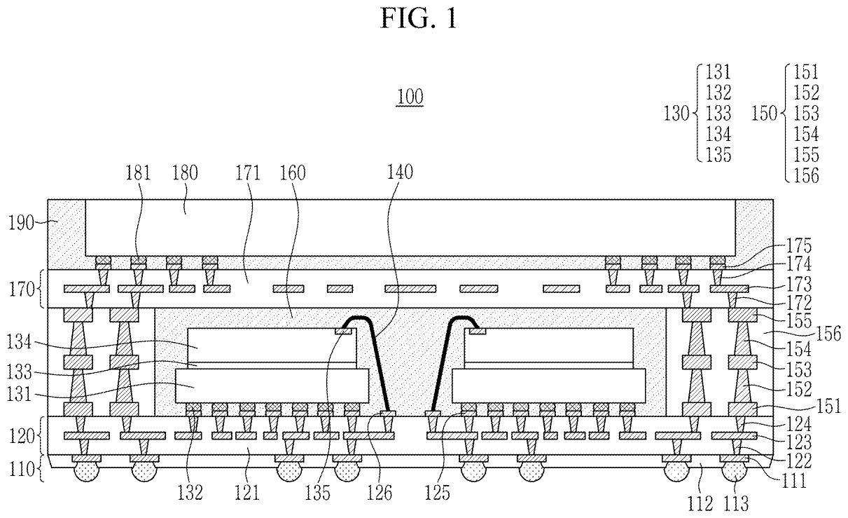

FIG. 1 illustrates a cross-sectional view showing a semiconductor package 100 according to an embodiment. The semiconductor package 100 may include a semiconductor stack structure 130 including a first semiconductor die 131 on a front side redistribution layer structure 120, and a second semiconductor die 134 positioned on the first semiconductor die 131 and not directly electrically connected to the first semiconductor die 131. For example, no direct chip-to-chip connection is made performed between the first semiconductor die 131 and the second semiconductor die 134.

Referring to FIG. 1, the semiconductor package 100 may include an external connection structure 110, a front side redistribution layer structure (first redistribution layer structure) 120, semiconductor stack structures 130, wires 140, a substrate 150, a first molding material 160, a back side redistribution layer structure (second redistribution layer structure) 170, a third semiconductor die 180, and a second molding material 190. Each semiconductor stack structure 130 may include a first semiconductor die 131 and a second semiconductor die 134 that are stacked on each other. In an embodiment, the semiconductor package 100 may include a package on package (POP). In an embodiment, the semiconductor package 100 may include a fan out wafer level package (FOWLP) or a fan out panel level package (FOPLP). In an embodiment, the semiconductor stack structure 130 may be a pre-manufactured three-dimensional integrated circuit structure having two or more semiconductor dies including the first and second semiconductor dies 131 and 134.

The external connection structure 110 may be positioned on a lower surface of the front side redistribution layer structure 120. The external connection structure 110 may include conductive pads 111, an insulating layer 112, and external connection members 113. The conductive pads 111 may electrically connect the first redistribution layer vias 122 of the front side redistribution layer structure 120 to the external connection members 113, respectively. The insulation layer 112 may include a plurality of openings for soldering. The insulating layer 112 may prevent the external connection member 113 from being short-circuited. The external connection member 113 may electrically connect the semiconductor package 100 to an external device (not illustrated).

The front side redistribution layer structure 120 may include a first dielectric layer 121, first redistribution layer vias 122, first redistribution layer lines 123, and second redistribution layer vias 124 within the first dielectric layer 121, and first bonding pads 125 and second bonding pads 126 on the first dielectric layer 121. In an embodiment, front side redistribution layer structures 120 may include fewer or greater redistribution layer lines, redistribution layer vias, and bonding pads.

The first dielectric layer 121 protects and insulates the first redistribution layer vias 122, the first redistribution layer lines 123, and the second redistribution layer vias 124. Semiconductor stack structures 130 and a substrate 150 may be positioned on an upper surface of the first dielectric layer 121. An external connection structure 110 may be positioned on a lower surface of the first dielectric layer 121.

The first redistribution layer via 122 may be positioned between the first redistribution layer line 123 and a conductive pad 111. The first redistribution layer via 122 may electrically connect the first redistribution layer line 123 to an external connection member 113 which is connected to the conductive pad 111 in a vertical direction. The first redistribution layer line 123 may be positioned between the first redistribution layer via 122 and the second redistribution layer via 124. The first redistribution layer line 123 may electrically connect the first redistribution layer via 122 and the second redistribution layer via 124 in a horizontal direction. The second redistribution layer via 124 may be positioned between the first bonding pad 125 and the first redistribution layer line 123. The second redistribution layer via 124 may electrically connect the first bonding pad 125 to the first redistribution layer line 123 and a second bonding pad 126 to the first redistribution layer line 123 in a vertical direction.

The first bonding pad 125 may be positioned between the second redistribution layer via 124 and a connection member 132 of the semiconductor stack structure 130. The first bonding pad 125 may electrically connect the connection member 132 of the semiconductor stack structure 130 to the second redistribution layer via 124 in the vertical direction.

The second bonding pads 126 may be positioned between the second redistribution layer vias 124 and the wires 140, respectively. The second bonding pads 126 may electrically connect the wires 140 to the second redistribution layer vias 124 in the vertical direction, respectively.

The semiconductor stack structure 130 may include a first semiconductor die 131, connection members 132, adhesive members 133, and a second semiconductor die 134. The semiconductor stack structure 130 may be positioned on the front side redistribution layer structure 120. A plurality of semiconductor stack structures 130 may be positioned on the front side redistribution layer structure 120. The semiconductor stack structures 130 may be positioned side by side on the front side redistribution layer structure 120.

The first semiconductor die 131 may be positioned between the adhesive member 133 and the connection members 132. The first semiconductor die 131 may be electrically connected to the connection members 132 and electrically insulated from the adhesive member 133. In an embodiment, the first semiconductor die 131 may include at least one of a central processing unit (CPU) and a graphics processing unit (GPU). The first semiconductor die 131 may have a first active region positioned at a surface of the first semiconductor die 131 (i.e., an active surface of the first semiconductor die 131) which is adjacent to the front side redistribution layer structure 120.

The connection members 132 may be positioned between the first semiconductor die 131 and the first bonding pads 125 of the front side redistribution layer structure 120. The connection members 132 may electrically connect the first semiconductor die 131 to the first bonding pads 125 of the front side redistribution layer structure 120. In an embodiment, the connection members 132 may include micro bumps or solder balls.

The adhesive member 133 may be positioned between the first semiconductor die 131 and the second semiconductor die 134. The adhesive member 133 may attach the first semiconductor die 131 to the second semiconductor die 134. The adhesive member 133 may electrically insulate the first semiconductor die 131 from the second semiconductor die 134. In an embodiment, the adhesive member 133 may include a die attach film (DAF).

The second semiconductor die 134 may be positioned on the adhesive member 133. The second semiconductor die 134 may be electrically connected to the front side redistribution layer structure 120 through wires 140, and may be electrically insulated from the first semiconductor die 131 by the adhesive member 133. In an embodiment, the second semiconductor die 134 may include at least one of a communication chip and a sensor. The second semiconductor die 134 may have a second active region positioned on a surface of the second semiconductor die 134 (i.e., an active surface of the second semiconductor die 134) which is adjacent to the back side redistribution layer structure 170. A footprint of the second semiconductor die 134 may be included within a footprint of the first semiconductor die 131. When viewed in a plan view, the second semiconductor die 132 may be disposed in an outer boundary of the first semiconductor die 131. The second semiconductor die 134 may include third bonding pads 135 which wires 140 contact, respectively. In an embodiment, the third bonding pads 135 may include at least one of copper, aluminum, silver, tin, gold, nickel, lead, titanium, and an alloy thereof. The term “contact,” as used herein, refers to a direct connection (i.e., physical touching) unless the context indicates otherwise.

The wires 140 may be positioned between the third bonding pads 135 of the second semiconductor die 134 and the second bonding pads 126 of the front side redistribution layer structure 120, respectively. The wires 140 may electrically connect the third bonding pads 135 of the second semiconductor die 134 to the second bonding pads 126 of the front side redistribution layer structure 120, respectively. A first end of each of the wires 140 may be electrically connected to a corresponding one of the third bonding pads 135 of the second semiconductor die 134, and a second end of each of the wires 140 may be electrically connected to a corresponding one of the second bonding pads 126 of the front side redistribution layer structure 120.

Conventionally, the second semiconductor die 134 of the semiconductor stack structure 130 was not directly electrically connected to the first semiconductor die 131, was electrically connected to the front side redistribution layer structure via the back side redistribution layer structure and the conductive posts, or was electrically connected to the first semiconductor die 131 via the back side redistribution layer structure, the conductive post, and the front side redistribution layer structure. Accordingly, conventionally, signals and power had no choice but to be transferred through long electrical paths between the second semiconductor die 134 and the first semiconductor die 131, and between the second semiconductor die 134 and the front side redistribution layer structure 120.

According to the present disclosure, a length of the electrical path may be reduced, and signal and power exchange between devices may occur more quickly by electrically connecting the second semiconductor die 134 to the front side redistribution layer structure 120 through the wires 140 so that the signal and power does not pass through the back side redistribution layer structure and the conductive posts, or by electrically connecting the second semiconductor die 134 to the first semiconductor die 131 through the wires 140 and the front side redistribution layer structure 120.

The substrate 150 may be positioned around the semiconductor stack structures 130 on the front side redistribution layer structure 120. The substrate 150 may be positioned to surround sides of the semiconductor stack structures 130 on the front side redistribution layer structure 120. The substrate 150 may include a first wiring layer 151, a first via 152, a second wiring layer 153, a second via 154, a third wiring layer 155, and an insulating layer 156. The substrate 150 may electrically connect the back side redistribution layer structure 170 to the front side redistribution layer structure 120. In an embodiment, the substrate 150 may include a printed circuit board (PCB). In an embodiment, the substrate 150 may include an embedded trace substrate (ETS). The ETS is a circuit board whose circuit pattern is in an insulating material. The ETS has a coreless structure, which allows for the implementation of microcircuits without the need for additional cost.

The first wiring layer 151 may be positioned between the second redistribution layer via 124 and the first via 152 of the front side redistribution layer structure 120. The first wiring layer 151 may electrically connect the first via 152 to the second redistribution layer via 124 of the front side redistribution layer structure 120 in a horizontal direction. The first via 152 may be positioned between the first wiring layer 151 and the second wiring layer 153. The first via 152 may electrically connect the second wiring layer 153 to the first wiring layer 151 in the vertical direction. The second wiring layer 153 may be disposed between the first via 152 and the second via 154. The second wiring layer 153 may electrically connect the second via 154 to the first via 152 in the horizontal direction. the second via 154 may be disposed between the second wiring layer 153 and the second wiring layer 153. The second via 154 may electrically connect the third wiring layer 155 to the second wiring layer 153 in the vertical direction. The third wiring layer 155 may be disposed between the second via 154 and the third redistribution layer via 172 of the back side redistribution layer structure 170. The third wiring layer 155 may electrically connect the third redistribution layer via 172 of the back side redistribution layer structure 170 to the second via 154 in the horizontal direction. The insulating layer 156 may surround and protect the first wiring layer 151, the first via 152, the second wiring layer 153, the second via 154, and the third wiring layer 155. In the embodiment of FIG. 1, the substrate 150 includes two layers of vias. The present invention, however, is not limited thereto. In an embodiment, the substrate 150 may include three or more multi-layers. In an embodiment, a substrate 150 that include fewer or greater numbers of wiring layers, and vias are within the scope of the present disclosure.

In an embodiment, the first via 152 and the second via 154 may have a truncated cone shape in which a diameter becomes narrower from a lower surface to an upper surface. In an embodiment, the first via 152 and the second via 154 may have a truncated cone shape in which a diameter becomes narrower from an upper surface to a lower surface. In an embodiment, the first via 152 and the second via 154 may include a cylindrical shape having a constant diameter from an upper surface to a lower surface.

In an embodiment, the insulating layer 156 may include a thermosetting resin such as an epoxy resin, a thermoplastic resin such as polyimide, or a mixture of such a resin and an inorganic filler. In an embodiment, the insulating layer 156 may include a resin impregnated into a core material such as glass fiber (glass fiber, glass cloth, glass fabric) together with an inorganic filler. In an embodiment, the insulating layer 156 may include prepreg, an ajinomoto build-up film (ABF), FR-4, or bismaleimide triazine (BT). In an embodiment, the insulating layer 156 may include a photosensitive dielectric (photoimageable dielectric PID)). In an embodiment, the first wiring layer 151, the second wiring layer 153, and the third wiring layer 155 may each include at least one of copper, aluminum, silver, tin, gold, nickel, lead, titanium, and an alloy thereof. In an embodiment, the first via 152 and the second via 154 may each include at least one of copper, aluminum, silver, tin, gold, nickel, lead, titanium, and an alloy thereof.

According to the present disclosure, the front side redistribution layer structure 120 and the back side redistribution layer structure 170 may be electrically connected by using a substrate (e.g., ETS) instead of a conductive post that was conventionally positioned between the front and back side redistribution layer structures. Accordingly, a length of the electrical path between the front side redistribution layer structure 120 and the back side redistribution layer structure 170 may be reduced, use of metal posts within the semiconductor package 100 may be reduced, a turnaround time may be reduced, and yield may be improved.

The first molding material 160 may be positioned on the front side redistribution layer structure 120, and may mold the semiconductor stack structures 130 and the wires 140 within the substrate 150.

The back side redistribution layer structure 170 may be positioned on the substrate 150 and the first molding material 160. The rear side redistribution layer structure 170 may include a second dielectric layer 171, a third redistribution layer vias 172, second redistribution layer lines 173, and fourth redistribution layer vias 174 within the second dielectric layer 171, and fourth bonding pads 175 on the second dielectric layer. In an embodiment, back side redistribution layer structures 170 that include fewer or greater redistribution layer lines, redistribution layer vias, and bonding pads are included within the scope of the present disclosure.

The second dielectric layer 171 protects and insulates the third redistribution layer vias 172, the second redistribution layer lines 173, and the fourth redistribution layer vias 174. A third semiconductor die 180 may be positioned on the upper surface of the second dielectric layer 171. The substrate 150 and the first molding material 160 may be positioned on a lower surface of the second dielectric layer 171.

The third redistribution layer via 172 may be positioned between the third wiring layer 155 and the second redistribution layer line 173 of the substrate 150. The third redistribution layer via 172 may electrically connect the second redistribution layer line 173 to the third wiring layer 155 of the substrate 150 in the vertical direction. The second redistribution layer line 173 may be positioned between the third redistribution layer via 172 and the fourth redistribution layer via 174. The second redistribution layer line 173 may electrically connect the third redistribution layer via 172 and the fourth redistribution layer via 174 in a horizontal direction. The fourth redistribution layer via 174 may be positioned between the second redistribution layer line 173 and the fourth bonding pad 175. The fourth redistribution layer via 174 may electrically connect the fourth bonding pad 175 to the second redistribution layer line 173 in the vertical direction. The fourth bonding pad 175 may be positioned between the fourth redistribution layer via 174 and the connection member 181 of the third semiconductor die 180. The fourth bonding pad 175 may electrically connect the connection member 181 of the third semiconductor die 180 to the fourth redistribution layer via 174.

The third semiconductor die 180 may be positioned on the back side redistribution layer structure 170. In an embodiment, the third semiconductor die 180 may include a memory structure. The third semiconductor die 180 may include connection members 181. The connection member 181 may electrically connect the third semiconductor die 180 to the back side redistribution layer structure 170. In an embodiment, the connection member 181 may include micro bumps or solder balls. In an embodiment, the connection member 181 may include at least one of tin, silver, lead, nickel, copper, and an alloy thereof.

The second molding material 190 may be positioned on the back side redistribution layer structure 170, and may mold the third semiconductor die 180.

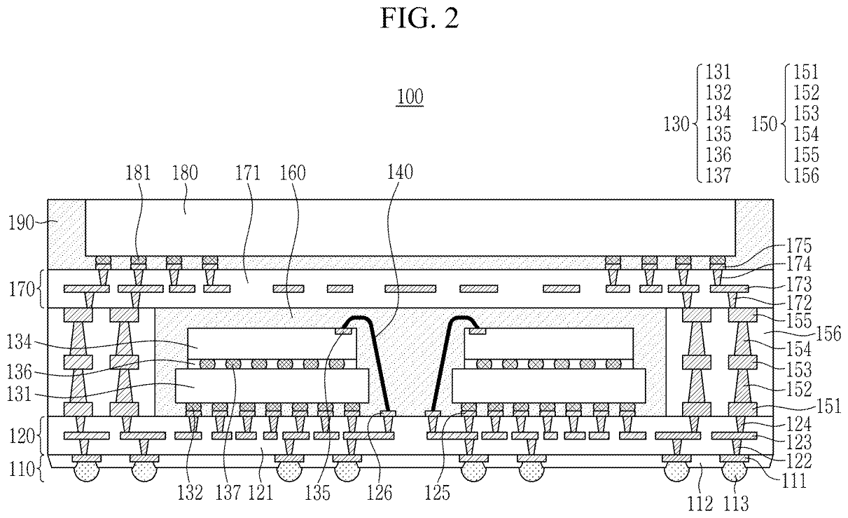

FIG. 2 illustrates a cross-sectional view showing the semiconductor package 100 according to an embodiment.

In FIG. 1, the first semiconductor die 131 and the second semiconductor die 134 of the semiconductor stack structure 130 are attached by the adhesive member 133, and unlike in the first semiconductor die 131 and the second semiconductor die 134 being electrically insulated from each other, in FIG. 2, an insulating member 136 and connection members 137 may be positioned between the first semiconductor die 131 and the second semiconductor die 134 of the semiconductor stack structure 130, and the first semiconductor die 131 and the second semiconductor die 134 may be electrically connected to each other. For example, the first semiconductor die 131 and the second semiconductor die 134 may be electrically connected with each other using the connection members 137. In an embodiment, the insulating member 136 may surround each of the connection members 137 for insulation thereof.

The semiconductor stack structure 130 may include the insulating member 136 and the connection members 137. The connection members 137 and the insulating member 136 may be positioned between the first semiconductor die 131 and the second semiconductor die 134. The connection member 137 may electrically connect the second semiconductor die 134 to the first semiconductor die 131. In an embodiment, the connection member 181 may include micro bumps or solder balls. In an embodiment, the connection member 181 may include at least one of tin, silver, lead, nickel, copper, and an alloy thereof. The insulating members 136 may surround and protect the connection members 137 between the first semiconductor die 131 and the second semiconductor die 134. In an embodiment, the insulating member 136 may include or may be a non-conductive film (NCF).

According to the present disclosure, the first semiconductor die 131 and the second semiconductor die 134 may exchange at least one of a signal and power with each other through the connection members 137. The second semiconductor die 134 may exchange at least one of a signal and power from the front side redistribution layer structure 120 through the wires 140. For example, the first semiconductor die 131 and the second semiconductor die 134 may exchange signals with each other through the connection members 137, and the second semiconductor die 134 may receive power through the wires 140. As a result, a wiring design for transferring signals and power may be diversified, and a size of the semiconductor stack structure 130 may be reduced by positioning the wires 140 for exchanging signals and power outside the semiconductor stack structure 130.

The configuration in FIG. 2 is the same as the configuration shown in FIG. 1 other than the connection members 137 and the insulating member 136 being positioned between the first semiconductor die 131 and the second semiconductor die 134 of the semiconductor stack structure 130. Accordingly, in the descriptions of FIG. 1 may be equally applied to the configurations other than the connection members 137 and the insulating member 136 being positioned between the first semiconductor die 131 and the second semiconductor die 134 of the semiconductor stack structure 130 in FIG. 2.

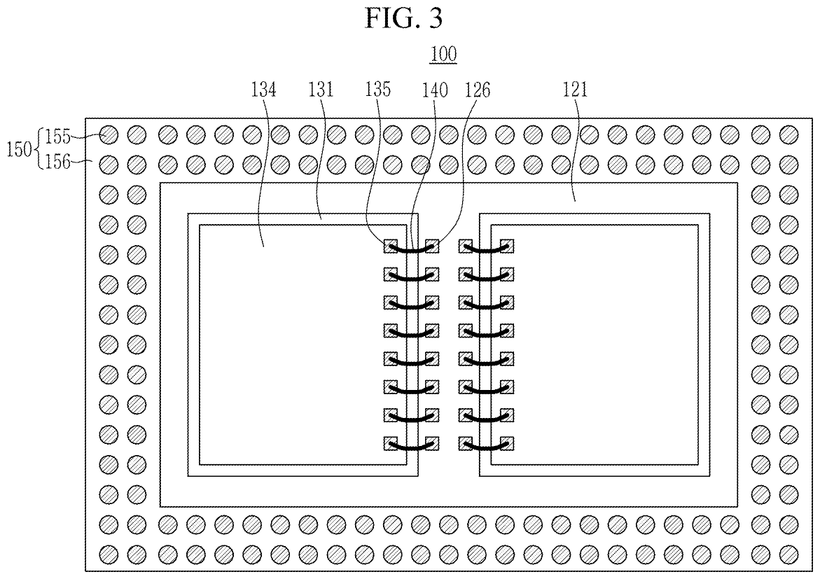

FIG. 3 illustrates a top plan view showing an upper surface of the semiconductor package 100 according to the embodiment of FIG. 1 and FIG. 2. FIG. 3 illustrates the upper surface of the semiconductor package 100 before being molded with the first molding material 160.

Referring to FIG. 3, the first semiconductor dies 131 and the substrate 150 may be positioned on the first dielectric layer 121 of the front side redistribution layer structure 120, and the second semiconductor die 134 may be positioned on each of the first semiconductor dies 131. In FIG. 2, a single substrate 150 integrally formed is illustrated surrounding the semiconductor stack structures 130, but the present disclosure is not limited thereto, and at least one of the substrates 150 and two or more separate substrates 150 surrounding the semiconductor stack structures 130 may be included in the present disclosure. In an embodiment, the single substrate 150 may include a through opening extending from an upper surface of the substrate 150 to a lower surface thereof. In an embodiment, two or more separate substrates 150 may be connected with each other to define a space to accommodate the semiconductor stack structures like the through opening of the single substrate 150.

The wires 140 may electrically connect the third bonding pads 135 of the second semiconductor die 134 and the second bonding pads 126 on the first dielectric layer 121 of the front side redistribution layer structure 120, respectively. According to FIG. 3, third bonding pads 135 of 8×1 are included on the upper surface of the second semiconductor die 134, second bonding pads 126 of 8×1 each are included on an upper surface of the first dielectric layer 121, and the wires 140 connect the third bonding pads to the second bonding pads, respectively. The present disclosure, however, is not limited thereto. In an embodiment, fewer or more bonding pads and wires may be included in the present disclosure.

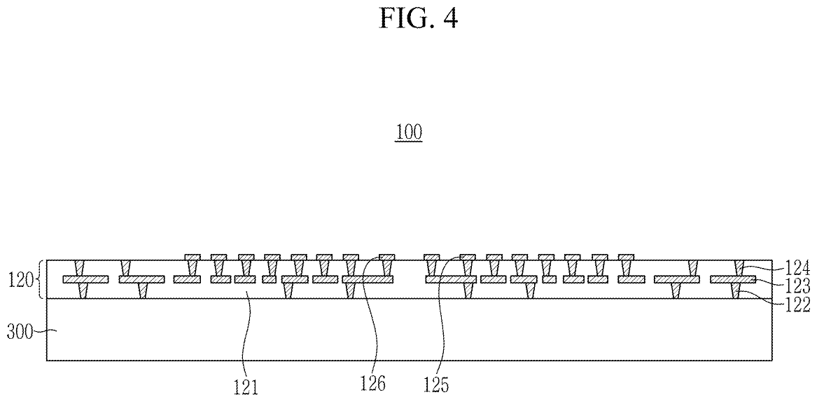

FIG. 4 illustrates a cross-sectional view showing steps of forming the front side redistribution layer structure 120 on a carrier 300.

Referring to FIG. 4, the front side redistribution layer structure 120 may be formed on the carrier 300. First, the carrier 300 may be provided. In an embodiment, the carrier 300 may include or may be formed of a silicon-based material such as glass and a silicon oxide, an organic material, an inorganic material such as an aluminum oxide, or a combination of these materials.

Next, the first dielectric layer 121 is positioned on the carrier 300. In an embodiment, the first dielectric layer 121 may include a photosensitive dielectric (photoimageable dielectric (PID)) used in a redistribution process. The photoimageable dielectric is finely patterned by using a photolithography process. As an embodiment, the photoimageable dielectric (PID) may include a polyimide-based photosensitive polymer, a novolak-based photosensitive polymer, polybenzoxazole, a silicone-based polymer, an acrylate-based polymer, or an epoxy-based polymer. In an embodiment, the first dielectric layer 121 is formed of an inorganic dielectric material such as a silicon nitride and a silicon oxide. In an embodiment, the first dielectric layer 121 may be formed by a CVD, ALD, or PECVD process.

After forming the first dielectric layer 121, via holes may be formed by selectively etching the first dielectric layer 121, and the first redistribution layer vias 122 may be formed by filling the via holes with a conductive material.

Then, the first dielectric layer 121 may be deposited on the first redistribution layer vias 122 and the first dielectric layer 121, the additionally deposited first dielectric layer 121 may be selectively etched to form openings, and the first redistribution layer lines 123 may be formed by filling the openings with a conductive material.

Then, the first dielectric layer 121 may be deposited on the first redistribution layer lines 123 and the first dielectric layer 121, the deposited first dielectric layer 121 may be selectively etched to form via holes, and the second redistribution layer vias 124 may be formed by filling the via holes with a conductive material.

Next, photoresist (not illustrated) may be deposited on the second redistribution layer vias 124 and the first dielectric layer 121, a photoresist pattern including via holes may be formed by selectively exposing and developing the photoresist, and first bonding pads 125 and second bonding pads 126 may be formed by filling the via holes with a conductive material.

In an embodiment, the first redistribution layer vias 122, the first redistribution layer lines 123, the second redistribution layer vias 124, the first bonding pads 125, and the second bonding pads 126 may include or may be formed of at least one of copper, aluminum, tungsten, nickel, gold, tin, titanium, and an alloy thereof. In an embodiment, the first redistribution layer vias 122, the first redistribution layer lines 123, the second redistribution layer vias 124, the first bonding pads 125, and the second bonding pads 126 may be formed by performing a sputtering process. In an embodiment, the first redistribution layer vias 122, the first redistribution layer lines 123, the second redistribution layer vias 124, the first bonding pads 125, and the second bonding pads 126 may be formed by performing an electroplating process after forming a seed metal layer.

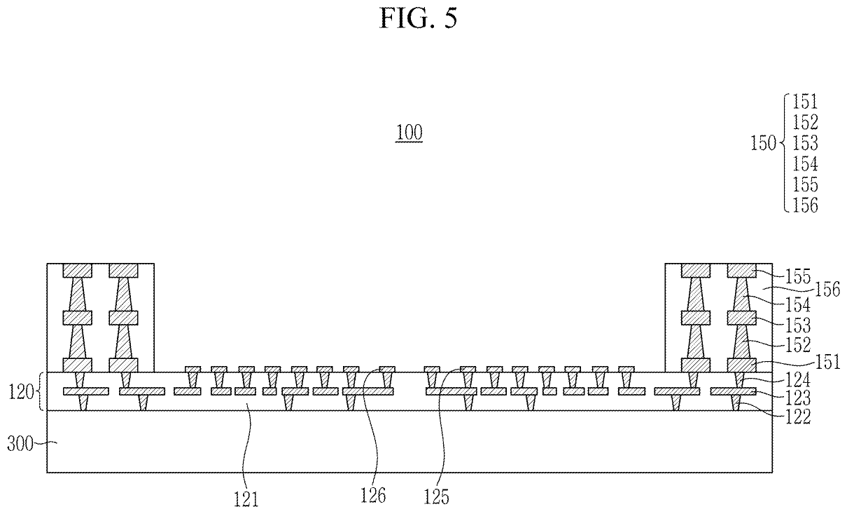

FIG. 5 illustrates a cross-sectional view showing a step of bonding the substrate 150 on the front side redistribution layer structure 120.

Referring to FIG. 5, the substrate 150 may be bonded to the front side redistribution layer structure 120 by performing a thermal compression (TC) process. The substrate 150 may include a through opening exposing the front side redistribution layer structure 120.

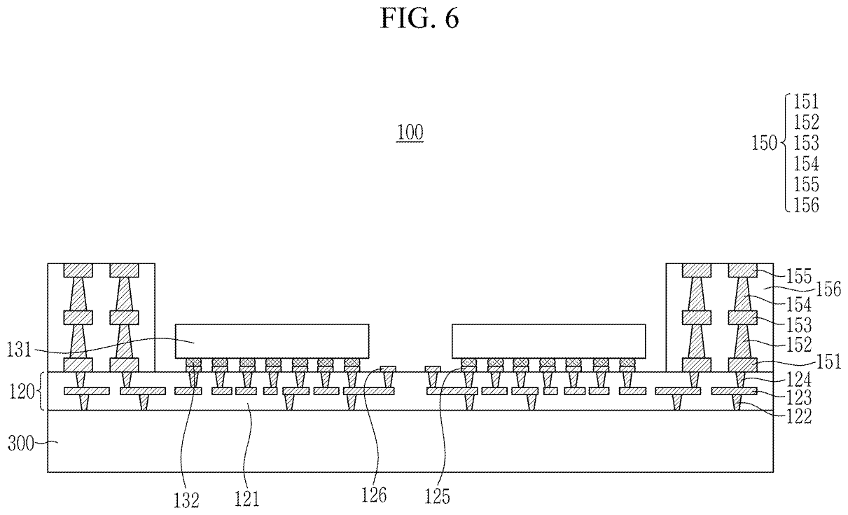

FIG. 6 illustrates a cross-sectional view showing a step of mounting the first semiconductor dies 131 on the front side redistribution layer structure 120.

Referring to FIG. 6, one or more first semiconductor dies 131 may be mounted on the front side redistribution layer structure 120 by flip chip bonding. In an embodiment, the one or more first semiconductor dies 131 may be disposed in the through opening. Each of the first semiconductor dies 131 may be positioned side by side and horizontally at a same level. The connection members 132 on a lower surface of the first semiconductor die 131 may be bonded to the second redistribution layer vias 124 of the front side redistribution layer structure 120, and may electrically connect the first semiconductor die 131 and the front side redistribution layer structure 120 with each other.

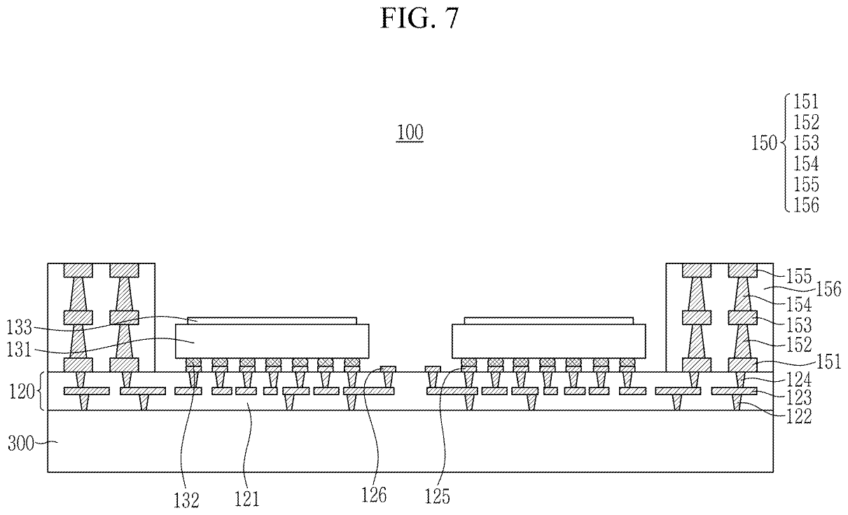

FIG. 7 illustrates a cross-sectional view showing a step of forming the adhesive member 133 on the first semiconductor dies 131.

Referring to FIG. 7, the adhesive member 133 may be positioned on the first semiconductor dies 131. In an embodiment, the adhesive member 133 may include or may be a die attach film (DAF).

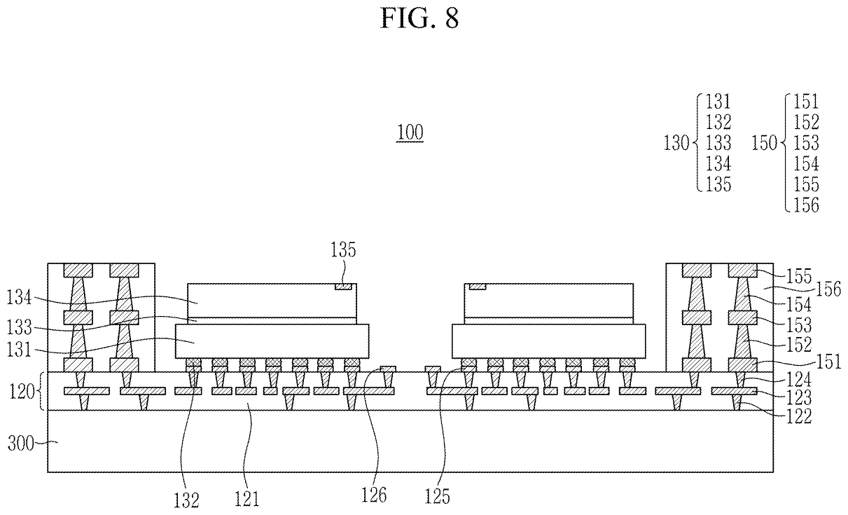

FIG. 8 illustrates a cross-sectional view showing a step of attaching the second semiconductor die 134 on the adhesive member 133.

Referring to FIG. 8, the second semiconductor die 134 may be attached on the adhesive member 133. The adhesive member 133 may electrically insulate the first semiconductor die 131 and the second semiconductor die 134 from each other.

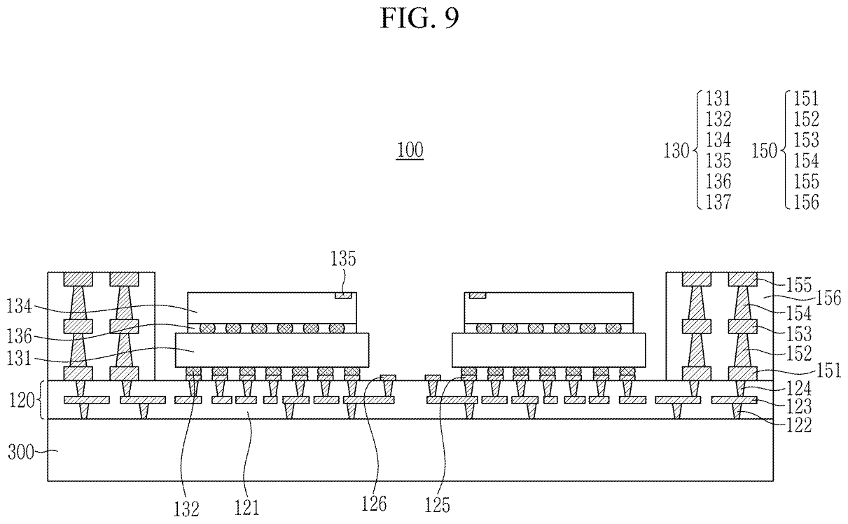

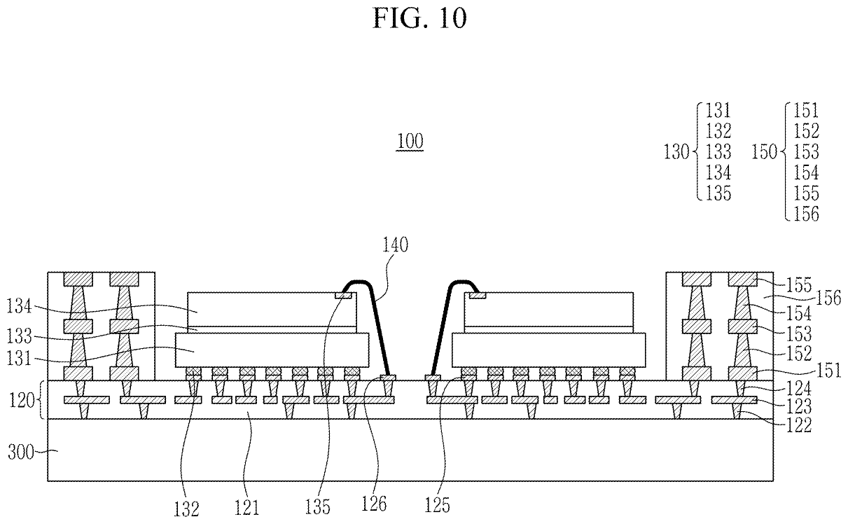

FIG. 9 illustrates a cross-sectional view showing a step of flip chip bonding the second semiconductor die 134 to the first semiconductor die 131, following the step as described with reference to FIG. 7. FIG. 9 illustrates a cross-sectional view showing a manufacturing method of the semiconductor package 100 according to an embodiment of FIG. 2. The manufacturing method of the semiconductor package 100 according to the embodiment of FIG. 1 of FIG. 10 to FIG. 17 may be applied to the subsequent manufacturing method of the semiconductor package 100 according to an embodiment of FIG. 2.

Referring to FIG. 9, first, a non-conductive film (NCF) may be attached as the insulating member 136 on the first semiconductor die 131. The non-conductive film (NCF) has adhesive properties, and may be attached to the first semiconductor die 131. The non-conductive film (NCF) has an uncured state capable of being deformed by an external force. The non-conductive film (NCF) may be attached by heating at a temperature of about 170° C. to about 300° C. for about 1 second to about 20 seconds. As such, by positioning the insulating member 136, stress between the first semiconductor die 131 and the second semiconductor die 134 may be alleviated or relieved.

Next, the second semiconductor die 134 may be deposited on the non-conductive film (NCF). The connection members 137 provided on the second semiconductor die 134 may contact the first semiconductor die 131 through the non-conductive film (NCF). The first semiconductor die 131 and the second semiconductor die 134 may be electrically connected to each other by the connection members 137. In an embodiment, the connection members 137 may include micro bumps. In an embodiment, the connection members 137 may include at least one of tin, silver, lead, nickel, copper, and an alloy thereof.

FIG. 10 illustrates a cross-sectional view showing a step of connecting the second semiconductor die 134 and the front side redistribution layer structure 120 with the wire 140.

Referring to FIG. 10, the wire 140 may be bonded to the second bonding pad 126 and the third bonding pad 135 by using capillary (not illustrated) or wedge (not illustrated). In an embodiment, before bonding the wire 140 to the second bonding pad 126 and the third bonding pad 135, a surface treatment process may be performed on the second bonding pad 126 and the third bonding pad 135 such that surface roughness of the second bonding pad 126 and the third bonding pad 135 is reduced in order to improve adhesion. In an embodiment, the wire 140 may include at least one of gold, silver, copper, and an alloy thereof.

In an embodiment, the wire 140 may be bonded to the second bonding pad 126 and the third bonding pad 135 by performing a thermal compression process, an ultrasonic process, or a thermosonic process.

A thermocompression process may be performed by applying heat to a tip of a capillary to form a first end of the wire 140 into a ball shape, pressing the wire 140 to the second bonding pad 126 to which heat is applied through the capillary, and then shaping a second end of the wire 140 into a ball, and by pressing the wire 140 to the third bonding pad 135 to which heat is applied through the capillary. The ultrasonic process may be performed by positioning the wire 140 on the second bonding pad 126 and applies pressure and ultrasonic waves to a first end of the wire 140 through a wedge (not illustrated) to compress the wire 140 to the second bonding pad 126, and then positioning the wire 140 on the third bonding pad 135, and applying pressure and ultrasonic waves to a second end of the wire 140 through the wedge (not illustrated) to compress the wire 140 to the third bonding pad 135. The thermocompression process may be performed by applying heat to a tip of a capillary to shape a first end of the wire 140 into a ball shape, applying heat, pressure, and ultrasonic vibration to the capillary to compress the wire 140 on the second bonding pad 126, and then by shaping a second end of the wire 140 into a ball, and applying heat, pressure, and ultrasonic vibration through the capillary to compress the wire 140 to the third bonding pad 135.

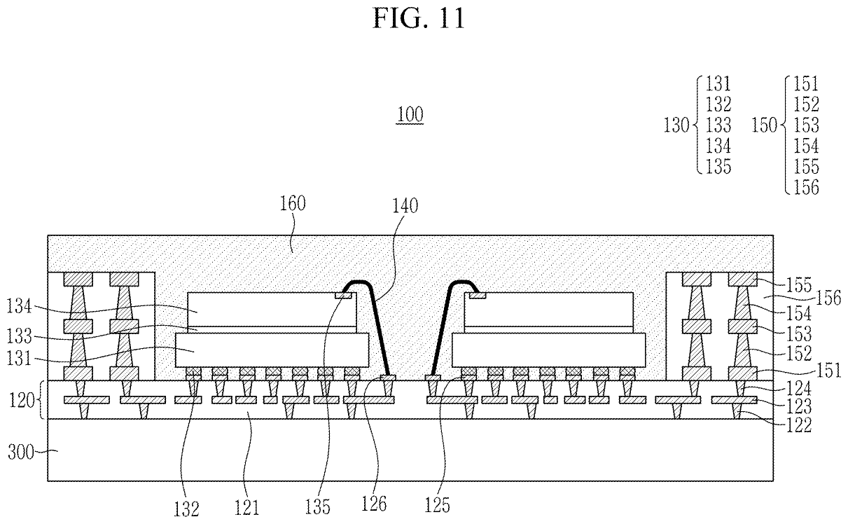

FIG. 11 illustrates a cross-sectional view showing a step of molding the semiconductor stack structures 130 and the wires 140 with the first molding material 160 on the front side redistribution layer structure 120.

Referring to FIG. 11, the semiconductor stack structures 130 and the wires 140 may be molded with the first molding material 160 on the front side redistribution layer structure 120 and within the substrate 150. In an embodiment, the molding process with the first molding material 160 may include a compression molding or transfer molding process. In an embodiment, the first molding material 160 may include an epoxy molding compound (EMC). In an embodiment, the semiconductor stack structure may include or may be a pre-manufactured three-dimensional integrated circuit structure having similar stacked structure as described with reference to FIGS. 1 and 2.

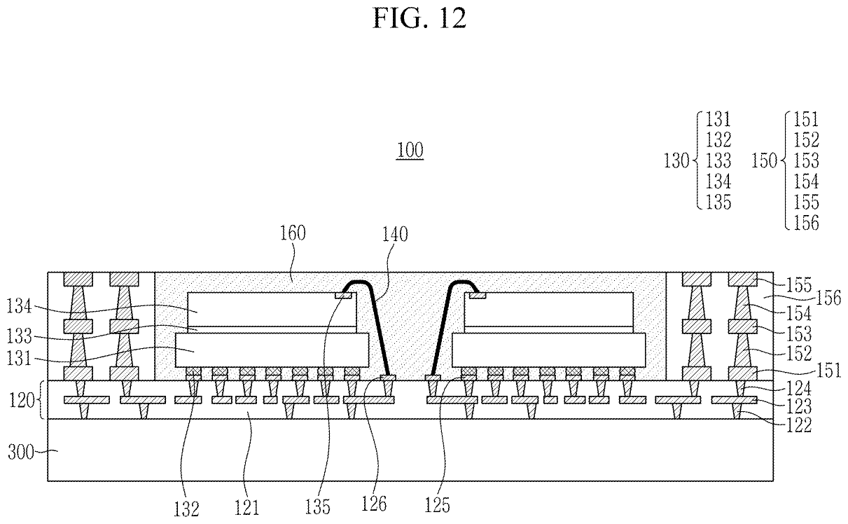

FIG. 12 illustrates a cross-sectional view showing a step of planarizing the first molding material 160.

Referring to FIG. 12, chemical mechanical polishing (CMP) may be performed to level an upper surface of the first molding material 160. An upper surface of the first molding material 160 may be planarized by applying a CMP process. After performing the CMP process, an upper surface of substrate 150 may be exposed.

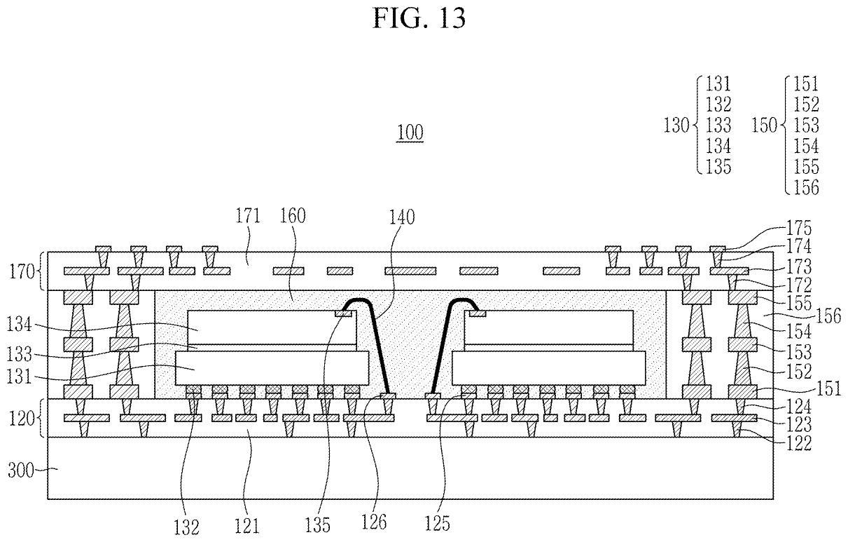

FIG. 13 illustrates a cross-sectional view showing a step of forming the back side redistribution layer structure 170 on the substrate 150 and the first molding material 160.

Referring to FIG. 13, the back side redistribution layer structure 170 may be positioned on the substrate 150 and the first molding material 160.

First, the second dielectric layer 171 is disposed on the substrate 150 and the first molding material 160. In an embodiment, the second dielectric layer 171 may include a photosensitive dielectric (photoimageable dielectric (PID)) used in a redistribution process. The photoimageable dielectric is a material capable of forming fine patterns by applying a photolithography process. As an embodiment, the photoimageable dielectric (PID) may include a polyimide-based photosensitive polymer, a novolak-based photosensitive polymer, polybenzoxazole, a silicon-based polymer, an acrylate-based polymer, or an epoxy-based polymer. In an embodiment, the second dielectric layer 171 is formed of an inorganic dielectric material such as a silicon nitride, and a silicon oxide. In an embodiment, the second dielectric layer 171 may be formed by a CVD, ALD, or PECVD process.

After forming the second dielectric layer 171, via holes may be formed by selectively etching the second dielectric layer 171, and the third redistribution layer vias 172 may be formed by filling the via holes with a conductive material.

Then, the second dielectric layer 171 may be deposited on the third redistribution layer vias 172 and the second dielectric layer 171, the additionally deposited second dielectric layer 171 may be selectively etched to form openings, and the second redistribution layer lines 173 may be formed by filling the openings with a conductive material.

Then, the second dielectric layer 171 may be deposited on the second redistribution layer lines 173 and the second dielectric layer 171, the deposited second dielectric layer 171 may be selectively etched to form via holes, and the fourth redistribution layer vias 174 may be formed by filling the via holes with a conductive material.

Next, photoresist (not illustrated) may be deposited on the fourth redistribution layer vias 174 and the second dielectric layer 171, a photoresist pattern including via holes may be formed by selectively exposing and developing the photoresist, and fourth bonding pads 175 may be formed by filling the via holes with a conductive material.

In an embodiment, the third redistribution layer vias 172, the second redistribution layer lines 173, the fourth redistribution layer vias 174, and the fourth bonding pads 175 may include at least one of copper, aluminum, tungsten, nickel, gold, tin, titanium, and an alloy thereof. In an embodiment, the third redistribution layer vias 172, the second redistribution layer lines 173, the fourth redistribution layer vias 174, and the fourth bonding pads 175 may be formed by performing a sputtering process. In an embodiment, the third redistribution layer vias 172, the second redistribution layer lines 173, the fourth redistribution layer vias 174, and the fourth bonding pads 175 may be formed by performing an electroplating process after forming a seed metal layer.

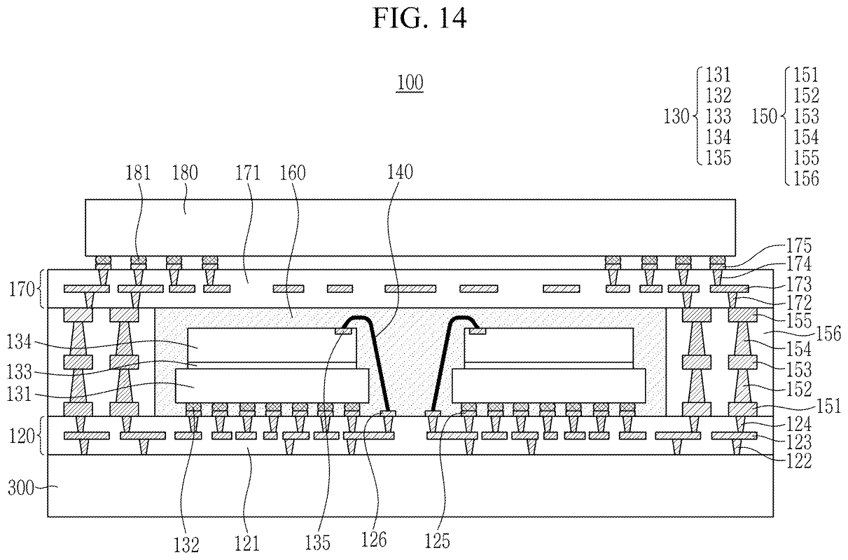

FIG. 14 illustrates a cross-sectional view showing a step of mounting the third semiconductor dies 180 on the back side redistribution layer structure 170.

Referring to FIG. 14, the third semiconductor die 180 may be mounted on the back side redistribution layer structure 170 by flip chip bonding. The connection member 181 of the third semiconductor die 180 may be bonded to the fourth bonding pad 175 of the back side redistribution layer structure 170, and thus the third semiconductor die 180 and the back side redistribution layer structure 170 may be electrically connected. In an embodiment, the connection member 181 may include micro bumps or solder balls.

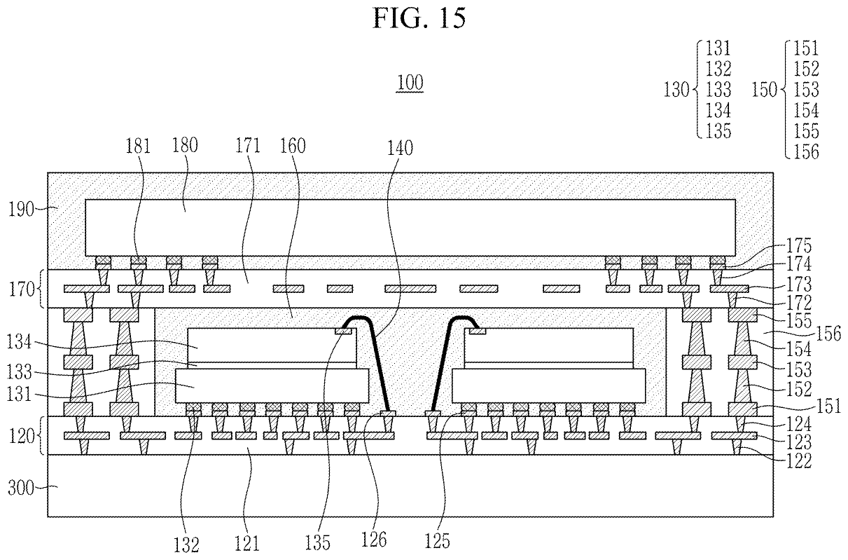

FIG. 15 illustrates a cross-sectional view showing a step of molding the third semiconductor die 180 with the second molding material 190 on the back side redistribution layer structure 170.

Referring to FIG. 15, the third semiconductor die 180 may be molded with the second molding material 190 on the back side redistribution layer structure 170. In an embodiment, the molding process with the second molding material 190 may include a compression molding or transfer molding process. In an embodiment, the second molding material 190 may include an epoxy molding compound (EMC).

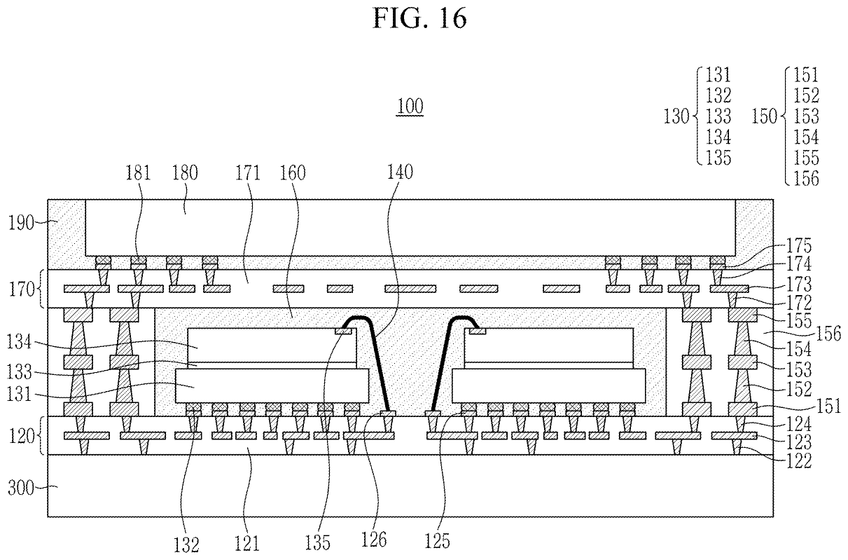

FIG. 16 illustrates a cross-sectional view showing a step of planarizing the second molding material 190.

Referring to FIG. 16, chemical mechanical polishing (CMP) may be performed to level an upper surface of the second molding material 190. An upper surface of the second molding material 190 may be planarized by applying a CMP process. After performing the CMP process, an upper surface of the third semiconductor die 180 may be exposed.

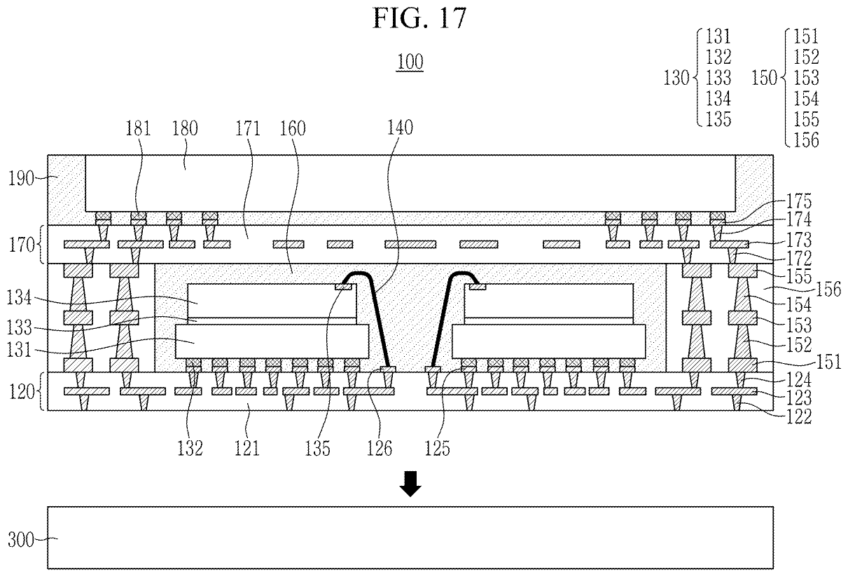

FIG. 17 illustrates a cross-sectional view illustrating a step of removing the carrier 300 from the front side redistribution layer structure 120.

Referring to FIG. 17, the carrier 300 may be removed from a lower surface of the front side redistribution layer structure 120.

Thereafter, as illustrated in FIG. 1, the external connection structure 110 may be positioned on the lower surface of the front side redistribution layer structure 120. Referring to FIG. 1, the external connection structure 110 may be formed on the front side redistribution layer structure 120. An insulating layer 112 may be disposed on a lower surface of the first dielectric layer 121 of the front side redistribution layer structure 120, and conductive pads 111 may be formed under the first redistribution layer vias 122. In an embodiment, the conductive pad 111 may include at least one of copper, nickel, zinc, gold, silver, platinum, palladium, chromium, titanium, and an alloy thereof. In an embodiment, the insulating layer 112 may include solder resist. In an embodiment, the external connection member 113 may include at least one of tin, silver, lead, nickel, copper, and an alloy thereof. In an embodiment, the conductive pad 111 may be formed by performing a sputtering process or an electrolytic plating process after forming a seed metal layer. In an embodiment, the insulating layer 112 may be formed by a CVD, ALD, or PECVD process.

While this invention has been described in connection with what is presently considered to be practical embodiments, it is to be understood that the invention is not limited to the disclosed embodiments, but, on the contrary, is intended to cover various modifications and equivalent arrangements included within the spirit and scope of the appended claims.

What is claimed is:

1. A semiconductor package comprising:
a first redistribution layer structure;
a semiconductor stack structure on the first redistribution layer structure, the semiconductor stack structure including a first semiconductor die and a second semiconductor die on the first semiconductor die;
a plurality of wires configured to electrically connect the second semiconductor die to the first redistribution layer structure;
a substrate on the first redistribution layer structure and around the semiconductor stack structure;
a molding layer molding the semiconductor stack structure and the plurality of wires which are on the first redistribution layer structure; and
a second redistribution layer structure on the molding layer.

2. The semiconductor package of claim 1,
wherein the substrate has a through opening exposing an upper surface of the first redistribution layer structure, wherein the semiconductor stack structure is disposed in the through opening,
wherein the molding layer fills the through opening, and
wherein the semiconductor stack structure further includes a die attach film between the first semiconductor die and the second semiconductor die.

3. The semiconductor package of claim 1,
wherein the first semiconductor die and the second semiconductor die are not directly electrically connected.

4. The semiconductor package of claim 1,
wherein the first semiconductor die and the second semiconductor die exchange signals through the plurality of wires and the first redistribution layer structure.

5. The semiconductor package of claim 1,
wherein the semiconductor stack structure includes a three-dimensional integrated circuit structure.

6. The semiconductor package of claim 5,
wherein the semiconductor stack structure further includes a plurality of connection members between the first semiconductor die and the second semiconductor die.

7. The semiconductor package of claim 6,
wherein the first semiconductor die and the second semiconductor die exchange signals through the plurality of connection members.

8. The semiconductor package of claim 6,
wherein the second semiconductor die receives power through the plurality of wires.

9. The semiconductor package of claim 1,
wherein a footprint of the second semiconductor die is disposed within a footprint of the first semiconductor die.

10. The semiconductor package of claim 1,
wherein the first semiconductor die includes a first active region positioned on a side adjacent to the first redistribution layer structure.

11. The semiconductor package of claim 1,
wherein the second semiconductor die includes a second active region positioned on a side adjacent to the second redistribution layer structure.

12. A semiconductor package comprising:
a first redistribution layer structure;
a plurality of first bonding pads on the first redistribution layer structure;
a plurality of second bonding pads on the first redistribution layer structure;
a plurality of semiconductor stack structures on the first bonding pads, each of the plurality of semiconductor stack structures including a first semiconductor die and a second semiconductor die on the first semiconductor die;
a plurality of wires configured to electrically connect the second semiconductor die to the first redistribution layer structure, a first end of each of the plurality of wires contacting each of the second bonding pads, and a second end of each of the plurality of wires contacting the second semiconductor die;
a substrate positioned side by side with the plurality of semiconductor stack structures and around the plurality of semiconductor stack structures on the first redistribution layer structure;
a molding material configured to mold the plurality of semiconductor stack structures and the plurality of wires on the first redistribution layer structure;
a second redistribution layer structure on the molding material; and
a third semiconductor die on the second redistribution layer structure.

13. The semiconductor package of claim 12,
wherein the substrate includes an embedded trace substrate.

14. The semiconductor package of claim 12,
wherein the first semiconductor die includes a central processing unit or a graphic processing unit.

15. The semiconductor package of claim 12,
wherein the second semiconductor die includes at least one of a communication chip and a sensor.

16. The semiconductor package of claim 12,
wherein the third semiconductor die includes a memory structure.

17. A manufacturing method of a semiconductor package, comprising:
forming a first redistribution layer structure;
bonding a substrate including a through opening onto the first redistribution layer structure, wherein the through opening exposes the first redistribution layer structure;
mounting a semiconductor stack structure on the first redistribution layer structure and within the through opening, the semiconductor stack structure including a first semiconductor die and a second semiconductor die on the first semiconductor die;
connecting the second semiconductor die to the first redistribution layer structure with a plurality of wires;
molding the semiconductor stack structure and the plurality of wires with a molding material on the first redistribution layer structure; and
mounting a second redistribution layer structure on the molding material.

18. The manufacturing method of claim 17,
wherein the mounting of the semiconductor stack structure on the first redistribution layer structure and within the through opening includes:
mounting the first semiconductor die on the first redistribution layer structure;
applying an adhesive member on the first semiconductor die; and
mounting the second semiconductor die on the first semiconductor die with the adhesive member.

19. The manufacturing method of claim 17,
wherein the semiconductor package includes a fan out wafer level package or a fan out panel level package.

20. The manufacturing method of claim 17,
wherein the semiconductor stack structure includes a pre-manufactured three-dimensional integrated circuit structure.
